(19) United States
(12) Patent Application Publication
(10) Pub. No.: US 2026/0040716 A1
(43) Pub. Date: Feb. 5, 2026

(54) SEMICONDUCTOR LIGHT-RECEIVING DEVICE

(71) Applicant: Sumitomo Electric Industries, Ltd., Osaka-shi, Osaka (JP)

(72) Inventor: Takashi KATO, Osaka-shi (JP)

(73) Assignee: Sumitomo Electric Industries, Ltd., Osaka-shi, Osaka (JP)

(21) Appl. No.: 18/657,284

(22) Filed: May 7, 2024

(30) Foreign Application Priority Data
May 19, 2023 (JP) 2023-082855

(51) Int. Cl. H10F 77/124; H10F 30/222

(52) U.S. Cl. CPC H10F 77/1248; H10F 30/222

(57) ABSTRACT

A semiconductor light-receiving device includes an indium phosphide substrate, a first III-V compound semiconductor layer of a first conductivity type, a second III-V compound semiconductor layer of a second conductivity type, and an optical absorption layer disposed between the first III-V compound semiconductor layer and the second III-V compound semiconductor layer. The first III-V compound semiconductor layer is disposed between the indium phosphide substrate and the optical absorption layer. The optical absorption layer has a type-II superlattice structure. The superlattice structure includes a gallium indium arsenide layer and a gallium arsenide antimonide layer. The gallium indium arsenide layer has a compression strain. The gallium arsenide antimonide layer has a tensile strain.

### CROSS REFERENCE TO RELATED APPLICATIONS

This application claims priority based on Japanese Patent Application No. 2023-082855 filed on May 19, 2023, and the entire contents of the Japanese patent application are incorporated herein by reference.

### TECHNICAL FIELD

The present disclosure relates to a semiconductor light-receiving device.

### BACKGROUND

Non-patent literature 1 (Baile Chen, et al, “SWIR/MWIR InP-Based p-i-n Photodiodes with InGaAs/GaAsSb Type-II Quantum Wells” IEEE JOURNAL OF QUANTUM ELECTRONICS, VOL. 47, NO. 9, September 2011) discloses a pin photodiode having a strain-compensated type-II superlattice structure on an n-type indium phosphide (InP) substrate. The superlattice structure includes gallium indium arsenide (GaInAs) layers and gallium arsenide antimonide (GaAsSb) layers. The GaInAs layer has a tensile strain. The GaAsSb layer has a compression strain.

Non-patent literature 2 (K. Sugimura, et al, “High-performance extended SWIR photodetectors using strain compensated InGaAs/GaAsSb type-II quantum wells” Proc. SPIE 10926, Quantum Sensing and Nano Electronics and Photonics XVI, 109260E (1 Feb. 2019); doi: 10.1117/12.2509148) discloses a pin photodiode having a strain-compensated type-II superlattice structure on an n-type InP substrate. The superlattice structure includes GaInAs layers and GaAsSb layers. The GaInAs layer has a tensile strain. The GaAsSb layer has a compression strain.

### SUMMARY

According to an embodiment of the present disclosure includes an indium phosphide substrate; a first III-V compound semiconductor layer of a first conductivity type; a second III-V compound semiconductor layer of a second conductivity type; and an optical absorption layer disposed between the first III-V compound semiconductor layer and the second III-V compound semiconductor layer. The first III-V compound semiconductor layer is disposed between the indium phosphide substrate and the optical absorption layer, the optical absorption layer has a type-II superlattice structure, the superlattice structure includes a gallium indium arsenide layer and a gallium arsenide antimonide layer, the gallium indium arsenide layer has a compression strain, and the gallium arsenide antimonide layer has a tensile strain.

### BRIEF DESCRIPTION OF THE DRAWINGS

FIG. 1 is a cross-sectional view schematically illustrating a semiconductor light-receiving device according to an embodiment.

FIG. 2 is a cross-sectional view schematically illustrating an optical absorption layer included in the semiconductor light-receiving device of FIG. 1.

FIG. 3 is a graph illustrating an example of a combination of a gallium fraction x of a GaₓIn₁₋ₓAs layer and an arsenic fraction y of a GaAs_{y}Sb_{1-y} layer.

FIG. 4 is a graph illustrating an example of the relationship between quantum efficiency and wavelength of the semiconductor light-receiving devices of a first experiment to a third experiment.

FIG. 5 is a graph illustrating an example of an energy band diagram in the semiconductor light-receiving device of a first experiment.

FIG. 6 is a graph illustrating an example of an energy band diagram in the semiconductor light-receiving device of a second experiment.

FIG. 7 is a graph illustrating an example of an energy band diagram of the semiconductor light-receiving device of a third experiment.

FIG. 8 is a graph illustrating an example of the relationship between quantum efficiency and wavelength of the semiconductor light-receiving device of a fourth experiment.

### DETAILED DESCRIPTION

When a GaInAs layer has a tensile strain and a GaAsSb layer has a compression strain, quantum efficiency may be reduced at a wavelength close to an absorption edge wavelength.

The present disclosure provides a semiconductor light-receiving device having high quantum efficiency at a wavelength close to the absorption edge wavelength.

### DESCRIPTION OF EMBODIMENTS OF PRESENT DISCLOSURE

First, embodiments of the present disclosure will be listed and described.

(1) A semiconductor light-receiving device includes an indium phosphide substrate; a first III-V compound semiconductor layer of a first conductivity type; a second III-V compound semiconductor layer of a second conductivity type; and an optical absorption layer disposed between the first III-V compound semiconductor layer and the second III-V compound semiconductor layer. The first III-V compound semiconductor layer is disposed between the indium phosphide substrate and the optical absorption layer, the optical absorption layer has a type-II superlattice structure, the superlattice structure includes a gallium indium arsenide layer and a gallium arsenide antimonide layer, the gallium indium arsenide layer has a compression strain, and the gallium arsenide antimonide layer has a tensile strain.

According to the semiconductor light-receiving device, high quantum efficiency can be obtained at a wavelength close to an absorption edge wavelength.

(2) In (1), the gallium indium arsenide layer may have a gallium fraction x of 0.17 or more.

In this case, the absolute value of the strain ε of the gallium indium arsenide layer is 2% or less, and thus lattice defects can be reduced.

(3) In (1) or (2), the gallium arsenide antimonide layer may have an arsenic fraction y of 0.78 or less.

In this case, the absolute value of the strain ε of the gallium arsenide antimonide layer is 2% or less, and thus lattice defects can be reduced.

(4) In any one of (1) to (3), the gallium indium arsenide layer may have a gallium fraction x of 0.46 or less.

(5) In any one of (1) to (4), the gallium arsenide antimonide layer may have an arsenic fraction y of 0.52 or more.

(6) In any one of (1) to (5), the gallium indium arsenide layer may include n gallium indium arsenide monomolecular layers, the gallium arsenide antimonide layer may include m gallium arsenide antimonide monomolecular layers, and n and m may be each an integer of 13 to 25.

(7) In any one of (1) to (6), y≤1.054x²−2.809x+1.594 may be satisfied, where x is a gallium fraction in the gallium indium arsenide layer, and y is an arsenic fraction in the gallium arsenide antimonide layer.

In this case, the strain in the entire optical absorption layer can be reduced. When the gallium indium arsenide layer includes 25 gallium indium arsenide monomolecular layers and the gallium arsenide antimonide layer includes 13 gallium arsenide antimonide monomolecular layers, the strain in the entire optical absorption layer is zero if the above equation is satisfied.

(8) In any one of (1) to (7), y≥0.137x²−0.627x+0.775 may be satisfied, where x is a gallium fraction in the gallium indium arsenide layer, and y is an arsenic fraction in the gallium arsenide antimonide layer.

In this case, the strain in the entire optical absorption layer can be reduced. When the gallium indium arsenide layer includes 13 gallium indium arsenide monomolecular layers and the gallium arsenide antimonide layer includes 25 gallium arsenide antimonide monomolecular layers, the strain in the entire optical absorption layer is zero if the above equation is satisfied.

### DETAILS OF EMBODIMENTS OF PRESENT DISCLOSURE

Hereinafter, embodiments of the present disclosure will be described in detail with reference to the accompanying drawings. In the description of the drawings, the same or equivalent elements are denoted by the same reference numerals, and redundant description thereof will be omitted.

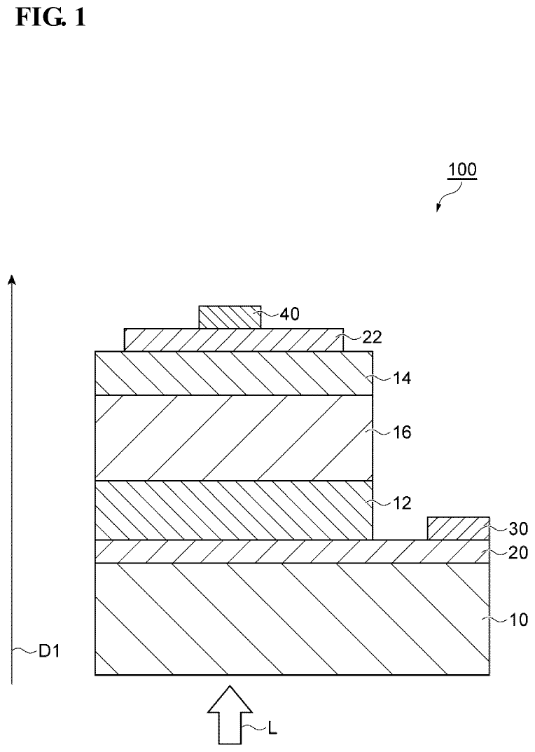

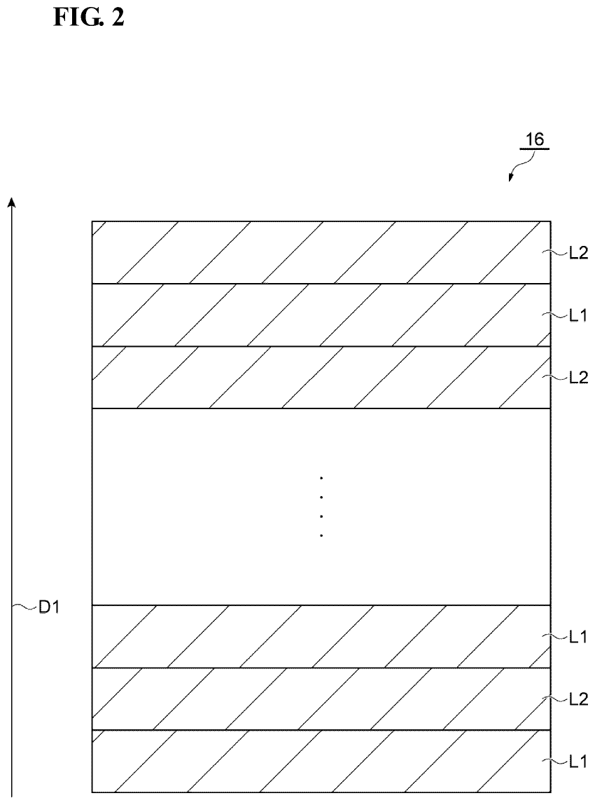

FIG. 1 is a cross-sectional view schematically illustrating a semiconductor light-receiving device according to an embodiment. FIG. 2 is a cross-sectional view schematically illustrating an optical absorption layer included in the semiconductor light-receiving device of FIG. 1. A semiconductor light-receiving device 100 shown in FIG. 1 is, for example, a photodiode. Semiconductor light-receiving device 100 includes an indium phosphide (InP) substrate 10, an n-type (first conductivity type) first III-V compound semiconductor layer 12, a p-type (second conductivity type) second III-V compound semiconductor layer 14, and an optical absorption layer 16. Optical absorption layer 16 is disposed between first III-V compound semiconductor layer 12 and second III-V compound semiconductor layer 14.

InP substrate 10 may be a semi-insulating substrate or an n-type substrate. First III-V compound semiconductor layer 12 may be disposed between the main surface of InP substrate 10 and optical absorption layer 16. The main surface of InP substrate 10 may be a (100) plane.

First III-V compound semiconductor layer 12 may be an n-type gallium indium arsenide (Gaₓ₁In₁₋ₓ₁As or GaInAs) layer, where x1 is a gallium (Ga) fraction, x1 is greater than 0 and less than 1, and x1 may be 0.46 to 0.48. An n-type dopant concentration in first III-V compound semiconductor layer 12 may be 5×10¹⁷ cm⁻³ to 3×10¹⁹ cm⁻³. The thickness of first III-V compound semiconductor layer 12 may be 0.2 μm to 3 μm.

Second III-V compound semiconductor layer 14 may be a p-type gallium indium arsenide (Gaₓ₂In₁₋ₓ₂As or GaInAs) layer, where x2 is a gallium (Ga) fraction, x2 is greater than 0 and less than 1, and x2 may be 0.46 to 0.48. A p-type dopant concentration in second III-V compound semiconductor layer 14 may be 5×10¹⁷ cm⁻³ to 3×10¹⁹ cm⁻³. The thickness of second III-V compound semiconductor layer 14 may be 0.2 μm to 3 μm.

Optical absorption layer 16 may be a non-doped III-V compound semiconductor layer. In the present specification, “non-doped” means that a dopant is not intentionally doped. Thus, a “non-doped” III-V compound semiconductor layer may have the p-type dopant concentration of less than 1×10¹⁵ cm⁻³ or the n-type dopant concentration of less than 1×10¹⁵ cm⁻³. Optical absorption layer 16 has a type-II superlattice structure.

As shown in FIG. 2, the superlattice structure of optical absorption layer 16 may include a gallium indium arsenide (GaₓIn₁₋ₓAs or GaInAs) layer L1 and a gallium arsenide antimonide (GaAs_{y}Sb_{1-y} or GaAsSb) layer L2. Each of GaₓIn₁₋ₓAs layer L1 and GaAs_{y}Sb_{1-y} layer L2 may be a non-doped layer.

GaₓIn₁₋ₓAs layer L1 has a compression strain, where x is a gallium (Ga) fraction. The Ga fraction x is larger than 0 and smaller than 0.468. When the Ga fraction x is smaller than 0.468, GaₓIn₁₋ₓAs layer L1 has a compression strain. The Ga fraction x of GaₓIn₁₋ₓAs layer L1 may be 0.17 or more, and may be 0.46 or less. When the Ga fraction x is 0.17 or more, the absolute value of the strain ε of GaₓIn₁₋ₓAs layer L1 is 2% or less. Thus, it is possible to reduce lattice defects in GaₓIn₁₋ₓAs layer L1. GaₓIn₁₋ₓAs layer L1 may include n GaₓIn₁₋ₓAs monomolecular layers, where n may be an integer of 13 to 25. The thickness of GaₓIn₁₋ₓAs layer L1 may be 3 nm to 8 nm.

GaAs_{y}Sb_{1-y} layer L2 has a tensile strain, where y is an arsenic (As) fraction. The As fraction y is larger than 0.512 and smaller than 1. When the As fraction y is larger than 0.512, GaAs_{y}Sb_{1-y} layer L2 has a tensile strain. The As fraction y of GaAs_{y}Sb₁₋ₓ layer L2 may be 0.52 or more, and may be 0.78 or less. When the As fraction y is 0.78 or less, the absolute value of the strain ε of GaAs_{y}Sb_{1-y} layer L2 is 2% or less. Thus, it is possible to reduce lattice defects in GaAs_{y}Sb_{1-y} layer L2. GaAs_{y}Sb_{1-y} layer L2 may include m GaAs_{y}Sb_{1-y} monomolecular layers, where m may be an integer of 13 to 25. The integer m may be the same as or different from the integer n. The thickness of GaAs_{y}Sb_{1-y} layer L2 may be 3 nm to 8 nm. The thickness of GaAs_{y}Sb_{1-y} layer L2 may be the same as or different from the thickness of GaₓIn₁₋ₓAs layer L1.

The strain ε of GaₓIn₁₋ₓAs layer L1 or GaAs_{y}Sb_{1-y} layer L2 is calculated by the following equation (1).

$$ε = ( a 1 - a 2 ) / a 2 \qquad ( 1 )$$

In the equation (1), a1 is a lattice constant of an InP substrate, and a2 is the lattice constant of GaₓIn₁₋ₓAs or GaAs_{y}Sb_{1-y} in the unstressed state.

At least one of the following equations (2) and (3) may be satisfied, where the Ga fraction is x, and the As fraction is y.

$$y \leq 1.054 {x}^{2} - 2.809 x + 1.594 \qquad ( 2 )$$

$$y \geq 0. 137 {x}^{2} - 0.627 x + 0.775 \qquad ( 3 )$$

When n is 25 and m is 13, if the above equation (2) is satisfied, the strain in the whole of optical absorption layer 16 is zero. When n is 13 and m is 25, if the above equation (3) is satisfied, the strain in the whole of optical absorption layer 16 is zero.

GaₓIn₁₋ₓAs layer L1 and GaAs_{y}Sb_{1-y} layer L2 may be alternately arranged along a first direction D1. GaₓIn₁₋ₓAs layer L1 may be disposed on a lower surface of optical absorption layer 16 closest to first III-V compound semiconductor layer 12. Thus, GaₓIn₁₋ₓAs layer L1 can be formed with good crystallinity on the semiconductor layer. GaAs_{y}Sb_{1-y} layer L2 may be disposed on an upper surface of optical absorption layer 16 closest to second III-V compound semiconductor layer 14. Thus, the semiconductor layer can be formed with good crystallinity on GaAs_{y}Sb_{1-y} layer L2. The number of pairs (periods) of GaₓIn₁₋ₓAs layer L1 and GaAs_{y}Sb_{1-y} layer L2 may be 200 to 400.

As shown in FIG. 1, semiconductor light-receiving device 100 may further include an n-type III-V compound semiconductor layer 20. III-V compound semiconductor layer 20 is disposed between InP substrate 10 and first III-V compound semiconductor layer 12. III-V compound semiconductor layer 20 may be a contact layer. III-V compound semiconductor layer 20 has the n-type dopant concentration higher than the n-type dopant concentration of first III-V compound semiconductor layer 12. III-V compound semiconductor layer 20 may be a GaInAs layer. An electrode 30 may be connected to III-V compound semiconductor layer 20.

Semiconductor light-receiving device 100 may further include a p-type III-V compound semiconductor layer 22. Second III-V compound semiconductor layer 14 is disposed between III-V compound semiconductor layer 22 and optical absorption layer 16. III-V compound semiconductor layer 22 may be a contact layer. III-V compound semiconductor layer 22 has the p-type dopant concentration higher than the p-type dopant concentration of second III-V compound semiconductor layer 14. III-V compound semiconductor layer 22 may be a GaInAs layer. An electrode 40 may be connected to III-V compound semiconductor layer 22.

InP substrate 10, III-V compound semiconductor layer 20, first III-V compound semiconductor layer 12, optical absorption layer 16, second III-V compound semiconductor layer 14, and III-V compound semiconductor layer 22 may be arranged in this order along first direction D1. First direction D1 may be orthogonal to the main surface of InP substrate 10. First direction D1 may be a thickness direction of optical absorption layer 16. First direction D1 may be a direction from first III-V compound semiconductor layer 12 toward second III-V compound semiconductor layer 14. First direction D1 may be a crystal growth direction.

Semiconductor light-receiving device 100 can detect incident light L. Incident light L may be visible light or infrared light having a wavelength of 0.4 μm to 4 μm. Incident light L may travel in first direction D1. Incident light L may be incident on optical absorption layer 16 through InP substrate 10. Semiconductor light-receiving device 100 may have an absorption edge wavelength (cutoff wavelength) of 2 μm to 4 μm or an absorption edge wavelength of 2.5 μm to 4 μm. Semiconductor light-receiving device 100 may be used in a spectroscopic system of a gas analyzer, an imaging system, or an optical communication system.

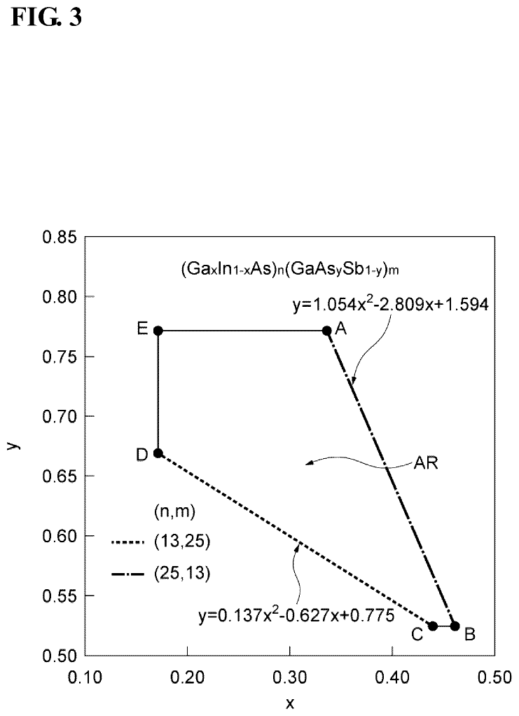

FIG. 3 is a graph illustrating an example of the combination of the Ga fraction x of GaₓIn₁₋ₓAs layer L1 and the As fraction y of GaAs_{y}Sb_{1-y} layer L2. In FIG. 3, the (x, y) coordinates of points A to E are as follows:
A (0.335, 0.772)
B (0.460, 0.525)
C (0.441, 0.525)
D (0.172, 0.671)
E (0.172, 0.772)

The combination of the Ga fraction x of GaₓIn₁₋ₓAs layer L1 and the As fraction y of GaAs_{y}Sb_{1-y} layer L2 may be located in an area AR surrounded by points A to E. That is, the Ga fraction x may be 0.17 to 0.46, the As fraction y may be 0.52 to 0.78, and both of the above equations (2) and (3) may be satisfied.

According to semiconductor light-receiving device 100, high quantum efficiency is obtained at a wavelength close to the absorption edge wavelength. The mechanism by which high quantum efficiency is obtained is considered as follows, but is not limited thereto.

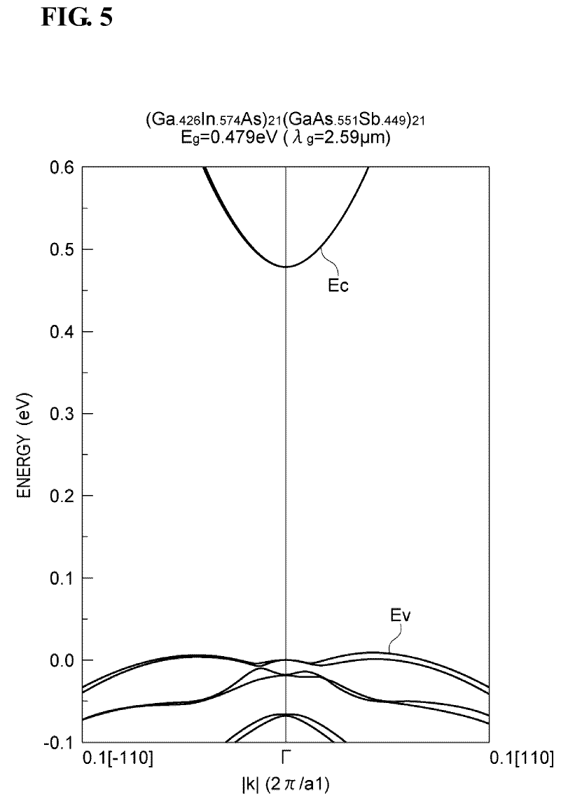

When GaₓIn₁₋ₓAs layer L1 has a compression strain and GaAs_{y}Sb_{1-y} layer L2 has a tensile strain, the energy at the upper end of a valance band corresponding to a wave vector shifted from a Γ point is increased in energy band diagrams (see FIGS. 5 to 7). As a result, the band gap energy decreases at the wave vector shifted from the Γ point, and thus optical transition (recombination of electrons and holes) is likely to occur at the wave vector. Since such optical transition occurs at a wavelength close to the absorption edge wavelength, the quantum efficiency is considered to be high at the wavelength.

In addition, when GaₓIn₁₋ₓAs layer L1 has a compression strain and GaAs_{y}Sb_{1-y} layer L2 has a tensile strain, the upper end of the valance band and lower energy levels are close to each other (see FIGS. 5 to 7). This is also considered as one of the reasons why high quantum efficiency can be obtained in semiconductor light-receiving device 100.

Hereinafter, various experiments performed for evaluating semiconductor light-receiving device 100 will be described. The experiments described below are not intended to limit the invention.

### First Experiment

The semiconductor light-receiving device of a first experiment includes an optical absorption layer disposed on an InP substrate. The thickness of the optical absorption layer is 2.5 μm. The optical absorption layer has a type-II superlattice structure. The superlattice structure includes a GaₓIn₁₋ₓAs layer and a GaAs_{y}Sb_{1-y} layer. The GaₓIn₁₋ₓAs layer and the GaAs_{y}Sb_{1-y} layer are alternately stacked in the stacking direction (corresponding to first direction D1 in FIGS. 1 and 2). Each of the thicknesses of the GaₓIn₁₋ₓAs layer and the GaAs_{y}Sb_{1-y} layer is 6.3 nm. The Ga fraction x is 0.426. Thus, the GaₓIn₁₋ₓAs layer has a compression strain. The As fraction y is 0.551. Therefore, the GaAs_{y}Sb_{1-y} layer has a tensile strain. The GaₓIn₁₋ₓAs layer includes 21 GaₓIn₁₋ₓAs monomolecular layers. The GaAs_{y}Sb_{1-y} layer includes 21 GaAs_{y}Sb_{1-y} layer monomolecular layers.

### Second Experiment

The semiconductor light-receiving device of a second experiment has the same configuration as that of the first experiment except for the following points. In the second experiment, the Ga fraction x is 0.468. The As fraction y is 0.512. Thus, each of the GaₓIn₁₋ₓAs layer and the GaAs_{y}Sb_{1-y} layer has no strain. The GaₓIn₁₋ₓAs layer includes 20 GaₓIn₁₋ₓAs monomolecular layers. The GaAs_{y}Sb_{1-y} layer includes 20 GaAs_{y}Sb_{1-y} monomolecular layers. Thus, each of the thicknesses of the GaₓIn₁₋ₓAs layer and the GaAs_{y}Sb_{1-y} layer is 6.0 nm.

### Third Experiment

The semiconductor light-receiving device of a third experiment has the same configuration as that of the second experiment except that the Ga fraction x is 0.510 and the As fraction y is 0.472. In the third experiment, the GaₓIn₁₋ₓAs layer has a tensile strain. The GaAs_{y}Sb_{1-y} layer has a compression strain. Each of the thicknesses of the GaₓIn₁₋ₓAs layer and the GaAs_{y}Sb_{1-y} layer is 6.0 nm.

### (Quantum Efficiency)

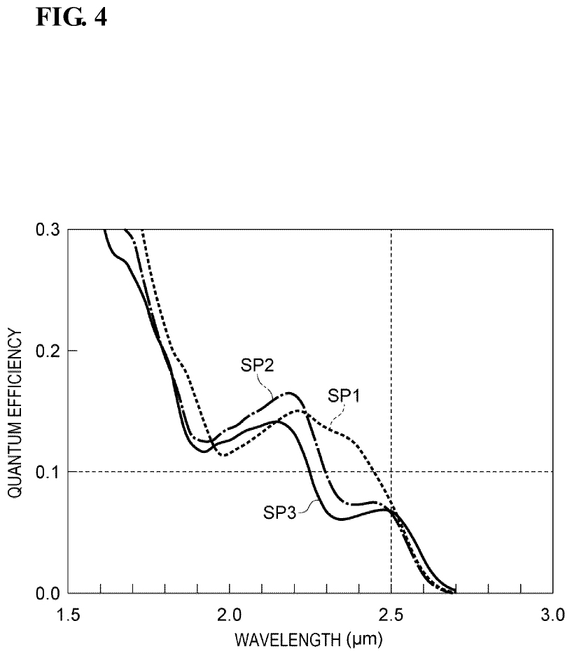

The quantum efficiencies with respect to the wavelength of light were calculated by simulation for the semiconductor light-receiving devices of the first experiment to the third experiment. The temperature used for the simulation is 250 Kelvin (K). The results of the simulation are shown in FIG. 4.

FIG. 4 is a graph illustrating an example of the relationships between the quantum efficiency and the wavelength of each semiconductor light-receiving device for the first experiment to the third experiment. In the graph of FIG. 4, the horizontal axis represents the wavelength (μm) of light absorbed by the optical absorption layer. The vertical axis represents the quantum efficiency of the semiconductor light-receiving device. A spectrum SP1 represents the quantum efficiency in the first experiment. A spectrum SP2 represents the quantum efficiency in the second experiment. A spectrum SP3 represents the quantum efficiency in the third experiment. As shown in FIG. 4, the absorption edge wavelength was about 2.7 μm in all of the first to third experiments. In a first wavelength region (for example, 2.3 μm to 2.5 μm) close to the absorption edge wavelength and a second wavelength region (for example, 1.8 μm to 1.9 μm) away from the absorption edge wavelength, the first experiment obtained higher quantum efficiency than the second experiment and the third experiment. In the first wavelength region close to the absorption edge wavelength, the quantum efficiency in the first experiment was larger than 0.1, and the quantum efficiencies in the second experiment and the third experiment were smaller than 0.1.

### (Energy Band Diagram)

Energy band diagrams were created by simulation for the semiconductor light-receiving devices of the first experiment to the third experiment. The temperature used for the simulation is 250 Kelvin (K). The results of the simulation are shown in FIGS. 5 to 7.

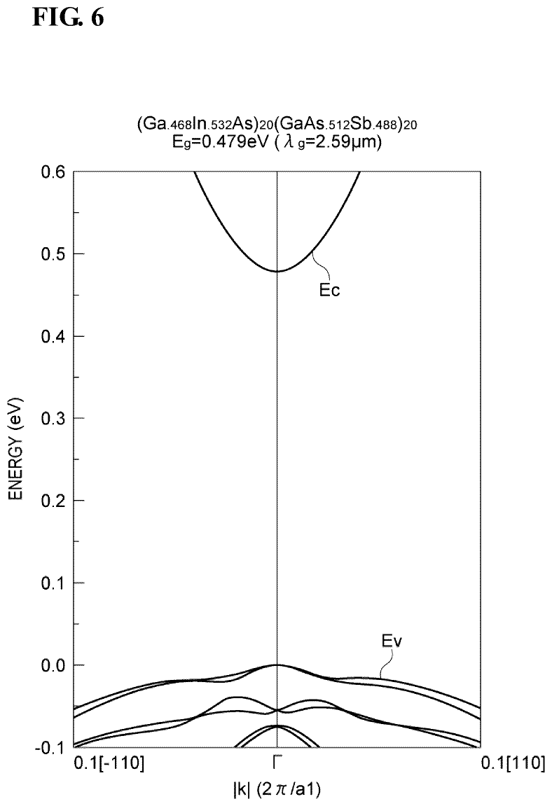

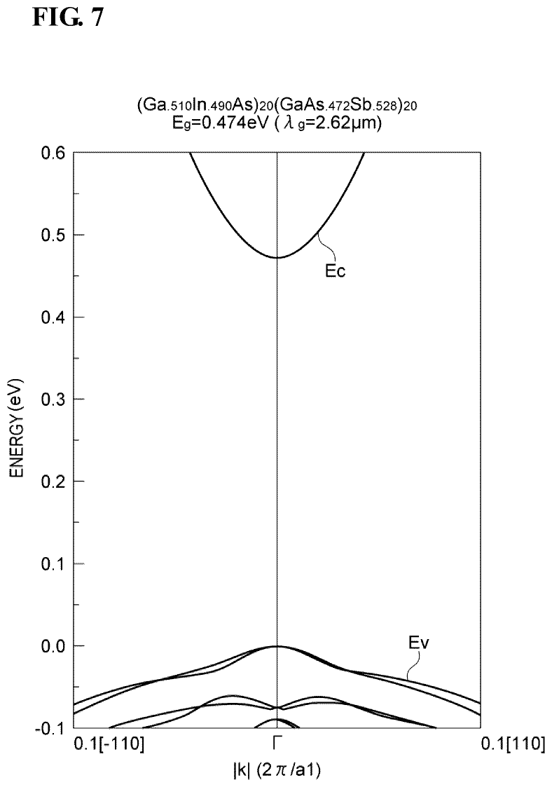

FIG. 5 is a graph illustrating an example of the energy band diagram in the semiconductor light-receiving device of the first experiment. FIG. 6 is a graph illustrating an example of the energy band diagram of the semiconductor light-receiving device in the second experiment. FIG. 7 is a graph illustrating an example of the energy band diagram of the semiconductor light-receiving device of the third experiment. In the graphs of FIGS. 5 to 7, the horizontal axis represents a value obtained by multiplying the absolute value of a wave vector k by (2π/a1), where a1 is the lattice constant of the InP substrate. [−110] and on the horizontal axis represent the directions of the wave vector k. The stacking direction of the GaₓIn₁₋ₓAs layer and the GaAs_{y}Sb_{1-y} layer is the z direction. In each graph, Ec represents the subband energy curve at the lower end of a conduction band, and Ev represents the subband energy curve at the upper end of the valence band. The energy at the upper end of the valence band has two values due to two spin orbitals. The lower energy levels having the energy lower than the upper end of the valence band also have two values.

As shown in FIG. 5, in the first experiment, a band gap energy Eg was 0.479 eV. That is, a band gap wavelength λg was 2.59 μm. As shown in FIG. 6, in the second experiment, the band gap energy Eg was 0.479 eV. That is, the band gap wavelength λg was 2.59 μm. As shown in FIG. 7, in the third experiment, the band gap energy Eg was 0.474 eV. That is, the band gap wavelength λg was 2.62 μm.

As shown in FIGS. 5 to 7, the energy band diagram in the first experiment was different from the energy band diagrams in the second experiment and the third experiment. One of the reasons why high quantum efficiency was obtained in the first experiment is considered to be the difference in energy band diagram.

In the first experiment, the upper end energy of the valence band corresponding to the wave vector shifted from the Γ point was larger than the energies in the second experiment and the third experiment. That is, in the first experiment, the curvature of the energy-wavevector curve of the upper end of the valance band near the Γ point becomes smaller, as compared with the second experiment and the third experiment. As a result, in the first experiment, the band gap energy is small at the wave vector shifted from the Γ point. Thus, optical transition (recombination of electrons and holes) is likely to occur at the wave vector. Since such optical transition occurs at a wavelength close to the absorption edge wavelength, the quantum efficiency is considered to be high at the wavelength.

In the first experiment, the distances between the upper end of the valence band and the lower energy levels were shorter than the distances in the second experiment and the third experiment. This is also considered to be one of the reasons why high quantum efficiency was obtained in the first experiment.

### Fourth Experiment

The semiconductor light-receiving device of a fourth experiment has the same configuration as that of the first experiment except for the following points. In the fourth experiment, the Ga fraction x is 0.221. Thus, the GaₓIn₁₋ₓAs layer has a compression strain. The As fraction y is 0.733. Thus, the GaAs Sb_{1-y} layer has a tensile strain. The GaₓIn₁₋ₓAs layer includes 13 GaₓIn₁₋ₓAs layer monomolecular layers. The GaAs_{y}Sb_{1-y} layer includes 15 GaAs_{y}Sb_{1-y} monomolecular layers. That is, the superlattice structure in the fourth experiment has a structure represented by (Ga_{0.221}In_{0.779}As)₁₃(GaAs_{0.733}Sb_{0.267})₁₅. In the fourth experiment, the band gap energy Eg was 0.472 eV. That is, the band gap wavelength ag was 2.628 μm.

### (Quantum Efficiency)

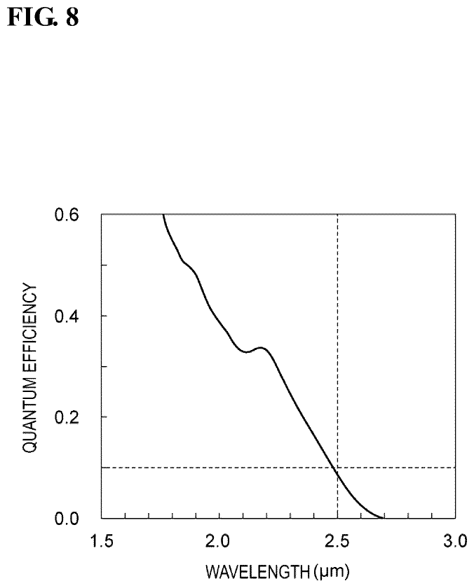

The quantum efficiency with respect to the wavelength of light was calculated by simulation for the semiconductor light-receiving device of the fourth experiment. The temperature used for the simulation is 250 Kelvin (K). The results of the simulation are shown in FIG. 8.

FIG. 8 is a graph illustrating an example of the relationship between the quantum efficiency and the wavelength of the semiconductor light-receiving device of the fourth experiment. The vertical axis and the horizontal axis of the graph of FIG. 8 are the same as the vertical axis and the horizontal axis of the graph of FIG. 4, respectively. As shown in FIG. 8, in the fourth experiment, high quantum efficiency of more than 0.1 was obtained in the first wavelength region (for example, 2.3 μm to 2.5 μm) close to the absorption edge wavelength and the second wavelength region (for example, 1.8 μm to 1.9 μm) away from the absorption edge wavelength.

Although the exemplary embodiments of the present invention have been described in detail, the present invention is not limited to the above-described embodiments.

The embodiments disclosed herein are to be considered in all respects as illustrative and not restrictive. The scope of the present invention is defined by the claims rather than the foregoing description, and is intended to include all modifications within the scope and meaning equivalent to the claims.

What is claimed is:

1. A semiconductor light-receiving device comprising:
an indium phosphide substrate;
a first III-V compound semiconductor layer of a first conductivity type;
a second III-V compound semiconductor layer of a second conductivity type; and
an optical absorption layer disposed between the first III-V compound semiconductor layer and the second III-V compound semiconductor layer,
wherein the first III-V compound semiconductor layer is disposed between the indium phosphide substrate and the optical absorption layer,
the optical absorption layer has a type-II superlattice structure,
the superlattice structure includes a gallium indium arsenide layer and a gallium arsenide antimonide layer,
the gallium indium arsenide layer has a compression strain, and
the gallium arsenide antimonide layer has a tensile strain.

2. The semiconductor light-receiving device according to claim 1, wherein the gallium indium arsenide layer has a gallium fraction x of 0.17 or more.

3. The semiconductor light-receiving device according to claim 1, wherein the gallium arsenide antimonide layer has an arsenic fraction y of 0.78 or less.

4. The semiconductor light-receiving device according to claim 1, wherein the gallium indium arsenide layer has a gallium fraction x of 0.46 or less.

5. The semiconductor light-receiving device according to claim 1, wherein the gallium arsenide antimonide layer has an arsenic fraction y of 0.52 or more.

6. The semiconductor light-receiving device according to claim 1,
wherein the gallium indium arsenide layer includes n gallium indium arsenide monomolecular layers,
the gallium arsenide antimonide layer includes m gallium arsenide antimonide monomolecular layers, and
n and m are each an integer of 13 to 25.

7. The semiconductor light-receiving device according to claim 1,
wherein y≤1.054x²−2.809x+1.594 is satisfied, where x is a gallium fraction in the gallium indium arsenide layer, and y is an arsenic fraction in the gallium arsenide antimonide layer.

8. The semiconductor light-receiving device according to claim 1,
wherein y≥0.137x²−0.627x+0.775 is satisfied, where x is a gallium fraction in the gallium indium arsenide layer, and y is an arsenic fraction in the gallium arsenide antimonide layer.
